(19) United States
(12) Patent Application Publication
(10) Pub. No.: US 2002/0109535 A1
(43) Pub. Date: Aug. 15, 2002

(54) Power on reset circuit arrangement

(75) Inventor: Amado Caliboso, Sunnyvale, CA (US)

Correspondence Address: Baker Botts LLP, One Shell Plaza, 910 Lousiana Street, Houston, TX, 77002-4995, US

(73) Assignee: TelCom Semiconductor, Inc.

(21) Appl. No.: 09/780,066

(22) Filed: Feb. 9, 2001

(51) Int. Cl. H03L 7/00

(52) U.S. Cl. 327/143

(57) ABSTRACT

A power on reset circuit continuously asserts a reset output signal to a reset logic state (e.g., RESET) during the recovery of a power supply voltage from an inoperative voltage level, e.g., zero volts, to an operative minimum voltage level. The reset circuit continues to assert the reset output to the reset Logic State for an additional, active reset interval after the power supply voltage is above the minimum operative level. At the end of the additional active reset interval, the reset output is released to an operational logic level (e.g, NOT-RESET or RESET\). Operative logic circuits receiving the reset output signal are thus provided with the active reset interval in which to perform their built-in reset functions after the power supply level is at or above the minimum operative level. At the expiration of the active reset interval, the power on reset circuit provides the subsequent operative circuits with the NON-RESET logic state to indicate normal operation can be resumed. The power on reset circuit has no continuous current paths between power supplies (other than negligible leakage currents) other than during the recovery time.

### BACKGROUND OF THE INVENTION

1. Field of the Invention

This invention relates to an improvement applicable to power-on-reset circuits that issue a reset or initializing signal to subsequent circuits, which signal is time-delayed from an initiating recovery of a power supply voltage from an off condition.

More specifically, the present invention relates to an improvement for power on reset circuit arrangements usable in an integrated circuit. The invention simultaneously provides a simple circuit structure that has no DC current path between the power supply and ground and draws no appreciable current through an active or passive device except during the power on reset delay at the onset of a power up cycle.

2. Previous Art

A power on reset circuit is defined as a circuit which issues a single reset event (a logic transition edge or one shot pulse) initiated by a power supply voltage recovering from an off condition (low or zero voltage) to a satisfactory high condition. The reset event is generally delayed by a predetermined delay time sufficiently to cause subsequent receiving circuits or functions that depend on a stable value for the power supply voltage to return (i.e. reset) to respective initial conditions, in response to the reset event that indicates the power supply voltage is at a satisfactory operating level.

Power on reset circuits available in the prior art require a means for establishing the predetermined delay between the time power supply voltage begins to recover until a later time at which the power supply voltage is considered stable. The time delay means generally includes a charging capacitor and a circuit for charging the capacitor, which circuit for charging the capacitor is composed of a resistor or a constant current power supply. The power on reset circuits in the prior art also include a function to issue a one shot pulse, in response to the end of the predetermined delay time, i.e., a signal indicating that the power supply is turned on.

Four typical power on reset circuits are described in: {PRIVATE}U.S. Pat. No., 4,489,394 by Borg, Dec. 18, 1984, “Microprocessor power on reset system”; {PRIVATE}U.S. Statutory Invention Registration, H497, by Piasecki, Jul. 5, 1988, “Ratioed power on reset circuit”; {PRIVATE}U.S. Pat. No., 5,930,129, by Sugimura, Jul. 27, 1999, “Power on reset circuit”; and {PRIVATE}U.S. Pat. No., 4,300,065 by

Remedi, et al., Nov. 10, 1981, “Power on reset circuit” (the '065 patent).

Remedi's circuit illustrated in FIG. 1 of the '065 patent, has a power on reset circuit which will provide an output pulse when the power supply voltage, V.sub.DD, exceeds the threshold voltage of an N-channel field effect transistor plus half a volt. In addition, Remedi asserts there is low power consumption by the circuit.

A resistor 10 is coupled from power supply terminal V.sub.DD to node 16. An N-channel field effect transistor 11 is coupled from node 16 to the power supply reference, illustrated as ground. Transistor 11 has its gate connected to its drain at node 16. Resistor 10 and transistor 11 serve as a threshold detector for the power on reset circuit. Thus at the outset this power on reset circuit inherently has a continuous DC current path from the power supply terminal to ground, whenever the power supply voltage exceeds the threshold of the transistor 11. This draws a non-zero DC current from the power supply during normal operation, after the power on reset circuit has completed its function of initializing following circuits.

Sugimura's patent '129 addresses simplifying circuit structure for a power on reset circuit. After showing several other examples of prior art power on reset circuits, Sugimura discloses embodiments of a POR that are relatively complex in numbers of components required.

It would be advantageous to have a power-on-reset circuit arrangement that was simpler in number of components and minimized or eliminated DC current flow when not needed for operating the POR function.

### SUMMARY

Advantages of the present power on reset circuit invention:

There are no DC current paths except leakage current through any of the components.

The power on reset circuit tracks the threshold voltage in the associated working circuit to which it is connected.

The power on reset circuit is implemented with few active devices.

The power on reset circuit may be implemented with no resistor elements.

The power on reset delay time may be implemented with fixed delay-setting capacitors or MOS devices connected in a gate to grounded drain-source connection.

Clamping diodes or transistors connected in diode equivalent configuration in alternate embodiments of the present invention prevent retention of stored charge that may disturb subsequent reset operation following rapid toggling of the power supply, high dV/dT (time rate-of-change of voltage) or brief interruptions of the power supply voltage.

Alternative implementations of the present power on reset invention may use transistors or diodes to discharge charging delay capacitors during a ramp of power supply line voltage from the maximum supply level to zero volts.

In one embodiment of the invention, bipolar transistors Q1 and Q2 are connected in a diode configuration and transistor configuration, respectively, to provide clamping diode and discharging transistor function. The clamp diode and discharge functions operate to prevent the reset circuit function from not resetting properly under conditions of high rate of change or rapid toggling of the power supply, and are described further below.

The power on reset (POR) circuit includes a fixed capacitor and a weak NMOS (n-channel) device in a voltage divider configuration. A weak PMOS (p-channel MOS) device is connected in series with the gate of another NMOS transistor. The other NMOS transistor is connected forming a charging capacitance Cn (118) between the gate connection to the drain of the p-mos transistor and its drain and source grounded to the negative supply (104). A first and second CMOS inverter pair, form a buffer amplifier connected with positive rail connection to the positive power supply (Vdd) and negative rail connection to ground (Vss). The buffer amplifier input is connected to the gate of the charging capacitor transistor and outputs an active LOW reset signal RESET\ to following circuitry.

The weak PMOS device has its source connected to a local power supply connection (POS). The local power supply POS is coupled to the positive system supply voltage Vdd. The capacitor C0 is connected between the PMOS transistor's source and gate terminals.

The weak NMOS transistor source connects to the local negative supply bus. The negative supply connects back to the chip (system) ground terminal, Vss. The weak NMOS transistor gate and drain commonly join to connect with the common connection of the PMOS gate and one end of the capacitor C0.

The weak PMOS transistor's drain joins to connect in common with the gate of the NMOS capacitor Cn and the input of the buffer amplifier.

The weak P-channel and weak NMOS transistor may be single transistors of long channel length, or they may be a respective plurality of drain-source and source-drain series connected transistors if required by circuit layout or simulation constraints. For typical embodiments of the POR invention the W/L ratio for the weak p-channel and weak n-channel transistors would be much less than 1 because of the necessity for having relatively long charging delays.

The fixed capacitor C0 and the weak n-channel act as a voltage divider from the positive supply to the negative supply. When VDD is recovering from a discharged state, for example zero volts, it charges from 0 toward its eventual final value, i.e., Vdd-max. capacitor C0 initially will be completely discharged to zero volts holding the p-channel off. As Vdd increases from zero, C0 will initially couple the increasing voltage directly to the high impedance node at the common junction of the gate of the p-channel and the drain of the turned off n-channel (and any stray capacitance thereat). If C0 is much, much greater than the stray capacitance at the turned off n-channel drain, C0 will couple almost all of the Vdd ramp voltage there. When Vdd ramps to approach the threshold of the first n-channel transistor (Vtn), the drain of the n-channel transistor will start to conduct the displacement current (e.g., CdV/dT) supplied by the capacitor C0. Increasing drain current at the drain node of the weak n-channel lowers the impedance at its drain and begins to divert displacement current (i.e., C0 dV/dt) coming through the capacitor C0 from the Vdd voltage ramp.

The n-channel will continue to conduct while the voltage at its drain begins to monotonically approach a value depending on its conductance, the size of the capacitor C0 and the rate of increase of the Vdd ramp. After a first delay interval, and the first n-channel drain begins to clamp the voltage at its drain at or slightly above the n-channel threshold, the increasing power supply voltage begins to charge the capacitor C0 further for a further second time interval until the voltage across C0 approaches the p-channel transistor threshold value.

At this time, the supply voltage Vdd is greater than the sum of the circuit n-channel threshold voltage plus the p-channel threshold voltage (i.e., Vtp+Vtn), and continues to increase. Operative CMOS circuits that are being driven by the reset circuit of the present invention, will thus have supplied to them, the necessary supply voltage required for resetting prior to being signaled they are released from a reset mode into an operational mode. The reset circuit of this invention is arranged to provide a continuous reset signal during the first and second time intervals, and to maintain the continuous reset signal until the expiration of an additional delay time by the circuit described below. The operative circuits receiving the reset signal from the reset circuit thus perform their built-in reset functions and await the release of the reset signal from the reset circuit.

After the power supply has reached a value greater than Vtn+Vtp and the p-channel transistor begins to conduct a charging current to the charging delay capacitance provided by the gate of the second n-channel (e.g., Cn), the voltage (e.g., Vcn) at the second gate capacitance will begin to increase from zero volts, charging toward the increasing ramp voltage Vdd.

For some additional interval of time after Vdd>Vtn+Vtp, the supply voltage will be greater than the sum of the n-channel threshold voltage and the p-channel threshold voltage, while the voltage at the gate capacitance of the second n-channel (e.g., Vcn) charges from zero toward the increasing power supply voltage.

In an integrated circuit embodiment, Capacitor Cn is typically an MOS transistor connected to effectively operate as a capacitor. For example the capacity is between the gate conductor above the thin gate oxide over the substrate comprising a transistor active region.

Generally circuits are reset by logic low-level. So a low level on the buffer output with operative supply voltage will reset them and a positive transition will indicated the reset is done.

The buffer between the charging node Vcn and its active low output is arranged so that its input threshold for switching, Vsv, is greater than a selected fraction of the instantaneous buffer supply voltage, that is also the same as the recovering Vdd. The weak p-channel and the delay capacitor Cn are selected so that the voltage, Vcn, on the capacitor, Cn, that drives the input of the buffer, is delayed below the buffer input threshold by the further additional delay time after Vdd reaches the operative supply value for the following circuits. The output of the buffer will therefore remain low during the recovery phase and the further delay time. This additional delay time allows the following circuits to operatively receive the low (RESET\) level from the buffer and be actively reset by their internal reset circuitry during the additional delay time using the operative supply value. The following circuits are then signaled to be released from reset upon receiving a NON-RESET i.e., high level signal from the POR circuit.

After the additional delay time, when Vcn reaches the selected switching threshold, Vsv, of the operative supply voltage value, Vcn causes the buffer to switch from a low to a high level, signaling the end of the reset period to the following circuits. The two inverters of one preferred embodiment of the buffer between Vcn and Vout provide a selected buffer switching-threshold. The length of the additional delay depends on how large the delay capacitance is, and how weak the weak p-channel is, similar to an RC time constant. It also depends on what the buffer threshold is. These are selected to provide an additional delay for the following circuits to be reset while the supply voltage is greater than the operative Vdd value, with the reset signal asserted.

At some later time Vcn is going to get fully charged and eventually will go all the way to the POS rail, because the gate of the weak p-channel is held to the Vtn of the weak n-channel transistor. When Vcn goes high Vout will go high as well. Since Vcn is charged all the way to the POS rail, the source and drain of the weak p-channel are at the same potential, POS. Since the node Vcn is coupled to ground through only through capacitance Cn, no DC current flows in the P-channel after Vcn is fully charged to POS.

With a CMOS buffer, no DC current flows in the buffer when Vcn is at the buffer positive supply voltage. The weak n-channel is also coupled to the positive supply through capacitor C0, so no DC current flows through it after C0 is fully charged.

Since the gate of the p-channel is held at Vtn above the negative rail by the weak n-channel, the p-channel remains turned on, holding node Vcn at the positive rail POS through the on resistance of p-channel.

Vout thus starts at low-level and continuously outputs a logic low that resets a following circuit having an active low reset input connected to Vout when the circuit supply voltage (Vdd) recovers enough to cause it to be operatively active. The additional delay provided by the weak p-channel, the capacitance Cn, and the buffer switching threshold enables the following circuits, operatively activated by the operative supply voltage value, to be fully reset before the buffer outputs the transition from low to high, indicating the end of the reset period.

C0 is important at the beginning of a reset recovery cycle when POS is starting to ramp up. Initially, with no voltage across the capacitor C0, the gate-drain connections of the weak n-channel follow the supply voltage coupled through C0, until they reach the threshold of the n-channel. Then any current charging C0 is shunted to ground by the n-channel, preventing the voltage at the gate of the weak n-channel from increasing significantly above Vtn. As POS continues to rise above Vtn and capacitor C0 charges further, the weak p-channel will start to turn on when the voltage across C0 has reached the PMOS threshold value, Vtp.

When the POS supply voltage reaches about Vtp1+Vtn1, the sum of thresholds of the weak p-channel and weak n-channel begins to turn on and charging current lop will begin to flow from the drain of weak p-channel into the charging node Vcn, i.e., the gate of the capacitor configured transistor Cn and the input of the buffer.

For a CMOS buffer formed of two series inverters, INV1 and INV2, during the time that POS voltage is charging from zero toward Vtp1+Vtn1, the inverters INV1 and INV2 are essentially inactive, i.e., turned off, so the output of INV1 will remain low, as will the output of INV2. When POS increases beyond Vtp2, inverter INV1 has its input still held essentially at ground by the capacitance of Cn (since the weak p-channel has not yet begun to charge it). The PMOS pull-up of inverter INV1 will begin to conduct and charge the input of inverter INV2 toward POS, tending to cause inverter INV2 to keep driving the output Vout low. The output of INV2, Vout, will thus be held low for a time 0<t<t2 following the initial ramp up of POS. Since Vout is the active low reset signal, (RESET\), the power on reset circuit 100 continues to hold the operative circuit (CMOS DFF 138) in its active reset state.

At about the same time that Vcn starts to increase from the charging current through the weak p-channel (e.g., t2 at V(POS)>Vtn1+Vtp1), the operative DFF circuit will become active, since it's transistors have the same nominal thresholds as the reset circuit 100. While the weak p-channel charges the capacitance Cn, the operative DFF circuit will perform it's built-in reset functions.

As long as Vcn is less than the switching threshold, Vsv, of INV1, Vout will remain low asserting RESET\ to the DFF. When Vcn exceeds Vsv, the POR output Vout will be driven high by the gain of the two inverters INV1, INV2. Vcn crosses Vsv as C0 charges toward Vdd by the charging current Icp from weak p-channel.

The total delay time from the onset of POS recovery at initial time t0 to the time Vout switches from VSS to Vdd (t-del,) will be the sum of a first delay where the voltage Vn1 144 at node 111 is about Vtn (t1), plus the time for POS to increase to about vtn1+vtp1 (delay t2−t1), plus the additional delay time required for the weak p-channel to charge the charging capacitance Cn from zero to the switching threshold Vsv of the buffer (delay t3−t2). This neglects the transition time of the inverters on the order of nano-seconds, which is essentially zero compared to a typical time delay t-del of m-secs., or hundreds of micro-secs.

Vout thus initially starts out low, then will continue to remain low until Vcn has charged to a voltage sufficient to cause the inverter pair INV1, INV2 to switch Vout high, indicating the reset delay is complete.

With a sufficiently long additional delay time, (t3−t2), provided by the selected capacitance Cn of the delay transistor, and sufficiently low charging current from the weak p-channel, POS will increase to an operative value for a time interval sufficient to cause circuits receiving the reset signal from the POR circuit to be reset by the active low output Vout before Vcn reaches a switching threshold value (Vsv) for the inverter pair (INV1, INV2).

For a typical CMOS buffer or inverter the switching threshold is e.g., about ½ the supply voltage. Thus a value for Vcn about ½ Vdd, would ordinarily be sufficient to cause the inverter pair, INV1, INV2 to switch. In order to provide enhanced margin for preventing inadvertent early indication of the end of reset, a preferred embodiment of the present invention provides a buffer input with two series NMOS transistors sized to increase the switching threshold Vsv to about ⅘ of Vdd. This provides an increased margin for the additional delay time. This ensures that the reset output Vout, switches from a low value (asserting reset) to high value (release reset) after sufficient delay time following the reset of the working circuits at an operative supply voltage value for Vdd.

The POR circuit of the present invention thus provides a single pulse with an edge (positive going reset release edge) delayed by a delay time t-del (414), suitable for resetting or initializing operational circuitry following a recovery of the supply voltage, Vdd to an operative level (i.e., Vtp+Vtn).

If the recovery rise time, tr, of the power supply voltage, POS, provided to the power on reset circuit and the operative circuits is very short, t-del will be a minimum value, (e.g., about t3−tg2), because the weak p-channel will nearly instantaneously begin to charge the delay capacitance Cn. However if POS rises very slowly, the weak p-channel will not be turned on as quickly and will charge Vcn more slowly.

The time delay, t-del, then is established by the relative magnitudes of the current provided by weak p-channel, e.g., current Icp, and the gate capacitance Cn provided by capacitor connected NMOS and the switching threshold of the buffer, Vsv. Regardless of the rise time of the supply voltage, Vdd, the additional delay available for the following circuits to reset and initialize will be at least equal to or greater than about Vsv* Cn(avg) /(icp) from the charge (i.e, current over time) voltage relation for capacitors and Cn(avg) is the average capacitance for the non-linear capacitance of the NMOS transistor.

As POS starts ramping up, the capacitor C0 first couples essentially all the increased voltage directly to the high impedance of the initially off n-channel. C0 continues to hold the weak p-channel off while it charges the gate-drain connection of the weak n-channel. After the gate-drain connection of the weak n-channel reaches its threshold voltage, Vtn, C0 then begins to charge and turn on the weak p-channel when the weak n-channel device begins to turn on and starts to hold the one node of the capacitor low. It is important that leakage current, lcn, be low in the weak n-channel. The capacitor C0 has to be large enough to overcome leakage current lcn in the weak n-channel. It is also important that capacitor C0 is large enough to initially hold the weak p-channel device off with zero volts across the source and gate as it couples the Vdd ramp to the weak n-channel, but then it's also important to that it be small enough so that the charging current through it can be clamped near Vtn above ground by the gate-drain connection of the weak n-channel which then holds one end of the C0 capacitance low.

### BRIEF DESCRIPTION OF THE DRAWINGS

FIG. 1 is a schematic of one embodiment of the present reset circuit invention.

FIGS. 2-6 depict simulated waveforms of the nodes of the circuit of FIG. 1 during power supply recovery events.

FIG. 7 depicts simulated waveforms of the nodes of the circuit of FIG. 1 during brief power supply interruptions and rapid toggling of the power supply voltage.

### DETAILED DESCRIPTION OF THE STRUCTURE AND MODES OF OPERATION

FIG. 100 is a schematic of an embodiment of the present invention implemented in a conventional n-well CMOS technology. This technology is characterized by having both P-and N-channel transistors electrically isolated from each other by reverse biased P-N junctions formed by n-well diffusions in a P-type substrate. This technology also enables the use of multiple PNP transistors whose collectors are inherently connected in common, collector grounded or more familiarly termed, common-collector configuration. These multiple common collector, PNP transistors are used to advantage in the first example of the present invention described here, but are not limiting in the scope of the claimed invention.

Other technologies can provide different elements that can be combined to enable the benefits and advantages provided by the present POR invention disclosed herein. It is known that reset circuits work best together with other circuits when they are on the same integrated circuit chip. The successful operation of initializing circuit function, i.e., the power on reset operation, for a CMOS digital circuit is shown here by simulated operation with a digital DATA type or D-flip-flop 138 having an active-low reset input, R\, connected to the output Vout of POR circuit 100. Since the power on reset circuit 100 and the digital flip-flop DFF are on the same die, the CMOS P- and N-channel transistors for both circuits have essentially the same threshold values, respectively, Vtp and Vtn. The power-on-reset for the exemplary DFF circuit by the power on reset circuit 100 is achieved if the reset signal being applied to the functional circuit DFF, is delayed until DFF is functional.

Simulation of the POR circuit 100 in operation with the example DFF shows the behavior of significant elements in the circuit and how they enable the desirable characteristics and features of the present invention. In the normal use of typical digital CMOS circuits, operational functionality begins when the supply voltage to which the circuits are connected becomes greater than the sum of the N-channel and P-channel device thresholds. This delay is commonly known as the power-on-reset delay, or power-on set-up time. The minimum reset delay set-up time must be sufficient to allow for the receiving digital circuit (DFF) to be sufficiently functional, that it can execute it's own internal reset operations to be reset into a known state after the supply voltage reaches and exceeds the sum-of-the-threshold value.

In the normal case, the operational speed of the functional circuit is one or more orders of magnitude times faster than the reset delay time. Therefore, it will be assumed that DFF will be functionally ready to receive a reset signal when the supply voltage Vdd is greater than the sum of the P-channel and N-channel thresholds.

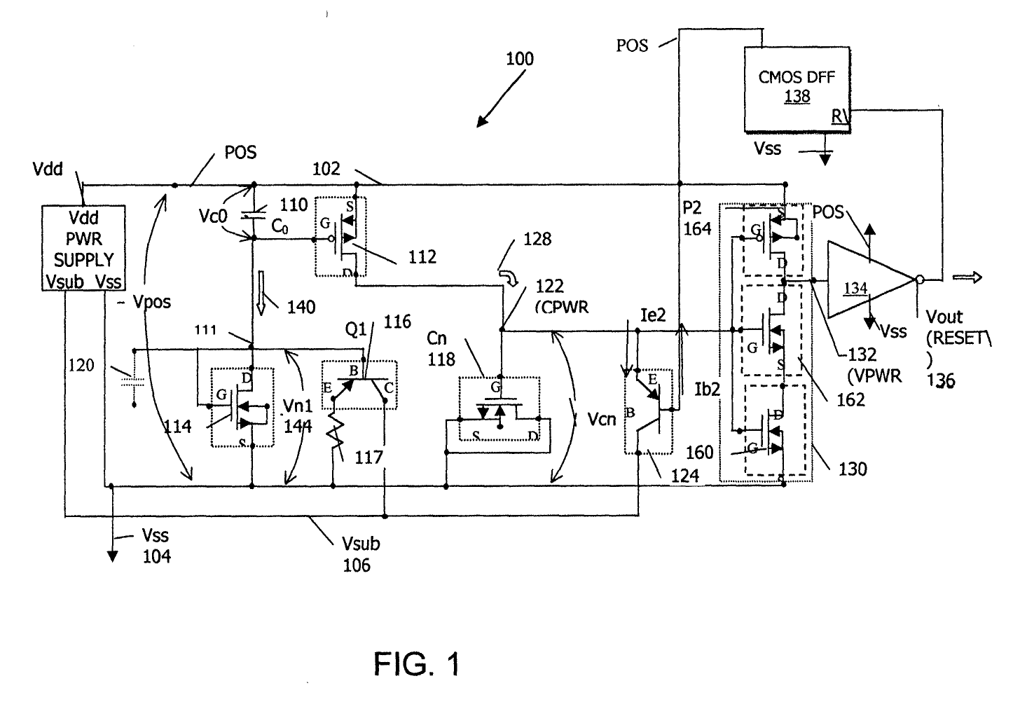

With respect to FIG. 1, there is shown the power on reset circuit 100 in accordance with the present invention. The POR circuit 100 and the CMOS DFF circuit 138 receive power from a common power supply rail 102 (POS). The positive power supply rail 102 connects to the (external) positive power supply output voltage, Vdd. The circuit 100 has a negative power supply rail 104 connected to power supply ground Vss, and a substrate rail 106 connected to a power supply substrate connection VSUB (generally the same as ground). The DFF circuit 138 also connects to the same power supply ground VSS and substrate VSUB connections.

Fixed capacitor 110 is connected at one end to positive power supply rail 102. The other end of capacitor 110 joins a common connection 111 with gate and drain terminals of a first n-channel transistor 114, a gate terminal of a first p-channel transistor 112 and a base terminal of a first PNP transistor 116. P-channel transistor 112 has its source terminal connected to the positive rail 102 and its drain terminal connected to another common terminal 122. Capacitor C0 110 is typically an internal capacitor in an integrated circuit embodiment of the present invention, but can alternatively be a fixed capacitor connected between external pins (not shown) connecting separately to the power supply terminal 102 and the charging node 111.

The n-channel transistor 114 has its source terminal connected to the negative rail 104. PNP transistor 116 has its collector terminal inherently connected to the substrate 106. Transistor 116 has its emitter coupled through a resistor 117 to the negative rail 104. P-channel transistor 112 has its drain connected to the gate of another n-channel transistor 118 and the emitter of another PNP transistor 124 at common connection 122. The source and drain of n-channel transistor 118 are connected to the negative rail 104. The collector of the PNP transistor 124 is also inherently connected to the substrate 106. PNP transistor 124 has its base connected to the positive rail 102.

A first CMOS inverter 130 has its input formed at the common junction 122. First inverter 130 includes a stack of two weak n-channel transistors 160 and 162 with respective drains, source and gate terminals. Transistor 160 has its source terminal connected to ground 104, its gate terminal connected in common with transistor gate terminal 162 and the common charging node 122. Transistor 162 has its source coupled to the drain of transistor 160 and its drain connected to the drain of a P-channel pull-up transistor 164.

Transistor 164 has its source terminal connected to the POS supply line 102 and its gate terminal connected in common with the gate terminals of the two weak n-channel transistors 160 and 162, at the common charging node 122. The common drain connections of n-channel transistor 162 and p-channel 164 form inverter 130's output terminal 132. The output 132 of CMOS inverter 130 is coupled as an input of a second CMOS inverter 134. The inverter 134 has its output 136 connected as reset bar (R\) input to the DFF flip-flop 138.

The second inverter 134 output 136 operates as the active low reset signal to the active-low reset input (R\) of flip-flop 138. The output 136 also provides a common active-low reset signal (Vout) capable of being distributed to multiple circuits (not shown) on the same IC chip.

This source and drain terminals of the n-channel transistor 118 are connected to the negative power supply rail VSS 104, and is configured thereby to function as a delay capacitor, Cn between its gate at the common junction 122 and ground 104.

Modes of Operation

There are three important reset operating conditions provided by the circuit 100 embodiment of the present power on reset invention. The first important mode of operation is to provide a continuous reset signal (active low) to the reset input (R\) of the flip-flop circuit 138 upon initial power up of the power supply Vdd. It is also important that the reset circuit 100 not release the reset signal 136 (i.e., allow it to go positive again) until a later time when the circuit 138 has accepted the active low reset signal R\ and has acted to complete its reset or initializing function.

The second important operation condition provided by the circuit embodiment 100 of the present invention is to provide and hold a valid reset signal when the power supply Vdd has a brief, temporary loss of power supply voltage, followed closely in time by a fast ramp up of power supply voltage.

The third important operation condition provided by the circuit embodiment 100 of the present power on reset invention by is to provide a valid reset signal to the circuit 138 after a rapid ramp up of power supply voltage following after only a short time interval from a rapid ramp down of power supply voltage, e.g., a rapid toggling of Vdd caused by rapidly disabling and enabling a switch or connection to a fixed voltage supply.

Mode One: Normal Operation, Initial Power Up with a Slow Ramp.

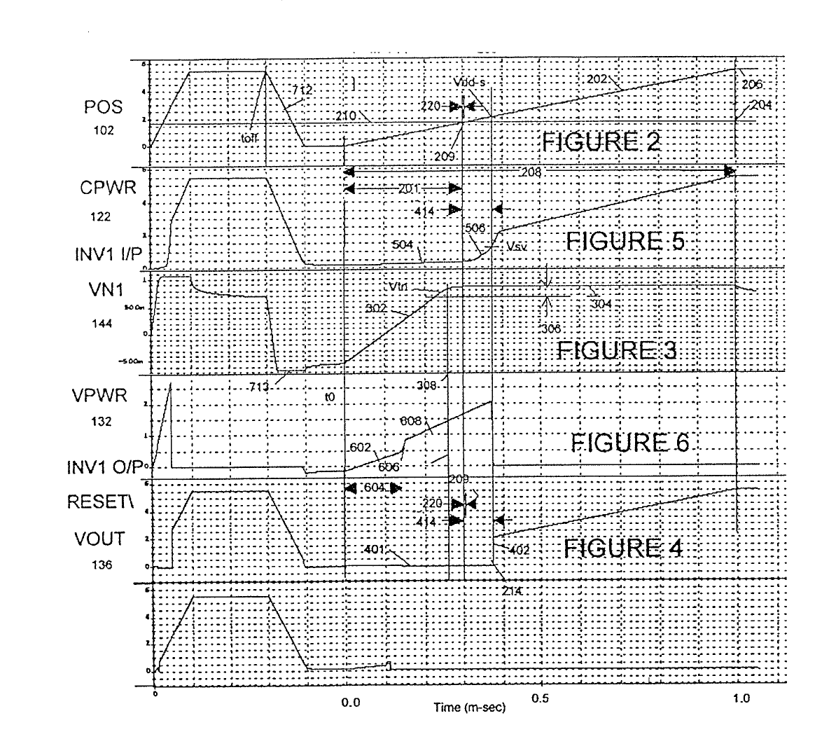

With regard to FIGS. 1, 2, 3, 4, 5, and 6, there are shown waveforms simulating operation of the circuit 100 during a simulated normal initial power up cycle in which the circuit 100 starts from equilibrium, that is, with all circuit nodes discharged to zero volts. Voltage waveforms shown in the graphs of FIGS. 2 through 6 assume a linear ramp of power supply voltage Vdd at the POS supply line going from zero volts to a maximum value, Vdd-max, with a linear slope 202. With regard to the schematic of FIG. 1, and the waveforms of FIG. 2, and FIG. 3, the power supply voltage Vdd starts from zero volts at an initial time point, t0. Vdd then increases linearly to Vdd-max at a final ramp time, tf, indicated by numeral 204. For the example shown here, the maximum voltage Vdd 206, is about 5.5 volts.

During an initial ramp interval 201 from initial time to t0 an intermediate later threshold time 209, the power supply voltage 202 increases to a first threshold voltage (vt1) 210. Voltage 210 is the arithmetic sum of the threshold voltage magnitude for the p-channel transistor 112 plus the threshold voltage magnitude for the n-channel transistor 114.

This can be expressed by the equation:

Vt1=|Vtn|+|Vtp| Equation 1

Prior to threshold time 209, the power supply voltage on the positive rail 102 is too low (i.e., less than Vt1) for the circuits of flip-flop 138 to operate functionally. Therefore the power on reset signal 136 must be asserted, i.e., held continuously low until the DFF 138 can be reliably reset. This is indicated in FIG. 4 by low voltage level 401 at the output 136, ranging from power supply turn on (initial time t0) over a time interval 201 to the later threshold time 209 where the DFF 138 will be reset as described below, providing a continuous active low reset input level 504 (FIG. 5) to the R\ input of DFF flip-flop 138.

Insight into operation of the reset circuit 100 between initial time t0 and threshold time 209, is provided by examining the voltage 144 (at node 111, in FIG. 3) across the stray capacitor 120 (Cs) and the n-channel transistor 114 between node 111 and ground, and the residual voltage, Vc0, across the first charging capacitor C0 connecting from the gate to source terminals of the p-channel transistor 112.

Capacitors C0 and Cs form a capacitive voltage divider as long as node 111 is below the Vtn of n-channel transistor 114. The ratio Cs/C0 is selected to be >>1 so initially almost all of the increasing Vdd appears across Cs capacitor 120. This is shown as the linear ramp 302 in FIG. 3 until the node 111 charges up so that node voltage 302 approaches the Vtn of transistor 114 at time point 308.

During the initial period 201 where Vdd<Vtn, (FIG. 2) following the turn on of the power supply most of the ramp voltage 202 appears across the stray capacitor, Cs, until the voltage at node 111 approaches Vtn at threshold time 203. Thus during most of the initial time interval 201 the first capacitor 110 keeps the gate source voltage of transistor 112 below its conduction threshold, Vtp. So the C0 capacitor 110 acts to hold the weak p-channel transistor 112 essentially off, i.e., essentially no drain current 128 (lcp) flows to charge node 122. The second charging capacitor 118 (Cn) therefore gets little or no charging current 128 from the p-channel device 112 during this time also. Thus the voltage 122 (Vcn) at the gate of transistor 118 remains at a low value (voltage 504<Vtn, FIG. 5) at or near Vss, while Vdd is ramping from 0 up to Vt1.

Since voltage 122 (Vcn) begins at 0 volts and continues to remain less than Vtn for a time after threshold time 209, the n-channel transistors 160 and 162 of first inverter 130 will be off throughout the initial interval 201. The p-channel pull-up 164 will also be off during an initial delay interval (interval 604, FIG. 6) following initial time t0. The off-transistors 160, 162 and 164 will act as capacitive voltage dividers during the interval 604 so the output 132 will begin to charge as an increasing ramp voltage (ramp 602, FIG. 6) between the POS ramp 202 and ground. Voltage ramp 602 on output 132 tends to drive the second inverter output 136 to remain at a low initial reset voltage level (voltage 401, FIG. 4), from sub-threshold leakage currents in the inverter 134 (not shown) despite its connection to the power supply POS.

Interval 604 ends when Vdd>Vtp at time point 606 and the p-channel pull-up 164 of the first inverter 130 quickly pulls up its output node 132 to follow the Vdd ramp 202 along voltage ramp 608. This turns on the second inverter 134 even harder so that the reset output voltage at node 136 remains at a low level 401 at source Vss.

As long as the voltage, Vcn, at node 122 is low, i.e., Vcn<Vtn, the first inverters p-channel pull-up 164 will be on since it has sufficient supply voltage Vdd>Vt1. Thus inverter output 132 will continue to charge up along ramp 608 following the Vdd ramp 202 (FIG. 6, showing the first inverter output 132 increasing essentially monotonically from time point 606 to threshold time 209) along with the POS supply line connected to Vdd ramp 202. The ramping inverter output 132 holds the second inverter output 136 low all through this interval (FIG. 4, from initial time t0 to threshold time 209), maintaining the reset signal, R\, (Vout at node 136) at a logic low, as desired. Thus the DFF circuit 138 is continuously held with its reset input R\ at active logic low 401 during the initial ramp up of Vdd from initial time t0 to threshold time 209.

Following the transition of transistor 114 from an off condition, or very low, sub-threshold leakage (not shown) to a conducting condition (FIG. 3 with the common gate-drain voltage 302 crossing Vtn at time point 308), the drain of 114 starts to clamp the node 111 at voltage limit 304.

As soon as the power supply voltage Vdd increases sufficiently so that Vdd=Vt1=Vtp+Vtn, CMOS flip-flop 138 is designed to operate functionally. As soon as DFF 138 is operational, the low voltage level 401 from node 136 applied to the active-low reset input R\ will be recognized as a valid reset signal and DFF 138 will perform its built-in reset operation.

In the example shown here, Vdd increases from zero volts at initial time t0 (ton) to a value equal to or greater than the first threshold voltage 210 (Vt1) at threshold time 209. When Vdd>Vt1, after threshold time 209, the internal P- and N-channel transistors (not shown) comprising DFF circuit 138 are provided with sufficient bias voltage to become active. With active transistors, built-in initialization circuitry (not shown) in the DFF 138 receive the low voltage reset level provided by the output 136 of circuit 100 and execute its internal reset and initialization routine within a few nano-seconds. This is indicated by the brief circuit initialization function interval 220 (shown in FIG. 2) following the threshold time 209 where Vdd>Vt1 (FIG. 2).

CMOS circuits like DFF 138 are characterized as having relatively brief circuit initialization function intervals, t-reset. The t-reset required for the dependent CMOS DFF 138 to reset its internal nodes will typically be only a few nano-seconds, even at supply voltages Vdd only slightly above the sum of the n- and p-channel thresholds.

The DFF 138 is now reset and ready to be activated for its intended use as soon as the reset input R\ is released from the active-low reset level which has been supplied by the output 136 of the reset circuit of the present invention.

Selection of Component Values

The reset circuit 100 provides a reset release interval, (trr, FIG. 6), following the time Vdd>Vtn at threshold time 209, until the circuit 100 release the reset signal 136, much longer than the initialization function interval 220 required for the circuit 138 to reset. This is demonstrated in the simulation waveforms of FIGS. 3-6 with regard to FIG. 1

The first charging delay capacitor 110 (C0) is selected so that C0 >>Cs, i.e., much larger relative to stray capacitance Cs at node 111, so that most of the initial voltage increase of Vdd from 0 to Vt1, appears across the stray capacitance 120 (Cs) as gate-source voltage 144 (111) for the n-channel transistor 114.

This keeps the p-channel device 112 in a non-conduction or sub-threshold conduction mode longer than the n-channel device 114, delaying thereby any significant charging current 128 from the drain of transistor 112. This further supports delaying a rapid increase in charging voltage Vcn at node 122 across the 2^{nd} delay capacitor provided by the gate of the common source-drain transistor 118.

After the n-channel transistor 114 begins to turn on at threshold time 203, the displacement current 140 coming from capacitor 110 is diverted from further increasing the voltage on the stray capacitance 120 into the drain of n-channel 114 connected in common at node 111. The drain-source voltage 144 at node 111 begins to tend toward a fixed plateau value 304 shown by the flattening of 111 in FIG. 4 around threshold time 209. The plateau voltage 304 is the sum of the n-channel threshold voltage, Vtn, of the n-channel transistor 114 plus an overdrive voltage, Vod (306). Vod is the product of the charging current 140 from capacitor 110 times the drain-source on-resistance of transistor 114.

Since the n-channel transistor 114 holds voltage 111 at nearly a constant Vtn+Vod, any further increase in the ramp voltage 202 is begins to appear across capacitor 110 and the gate-source terminals of weak p-channel 112. As mentioned previously, transistor 112 is a weak p-channel, i.e., a small W/L ratio transistor. Transistor 112 may be implemented as a single continuous rectangular geometry with narrow channel width Wp, and long channel length Lp (not shown) or as a combination of N source-drain series connected p-channel devices with shorter channel length Lp/N and common gate connection.

The voltage increase of Vcn at node 122 after Vdd>Vt1 is shown as waveform 506 in FIG. 5. Waveform 506 is seen to have approximately a power curve relationship. This comes about from the fact that drain current 128 is approximately a quadratic function of the increasing (Vdd−Vtn−Vtp). The current 128 flowing during the time of waveform 506 is integrated by the capacitance of transistor 118 (Cn) and appears approximately as a cubic function of the same voltage difference (Vdd−Vtn−Vtp).

Eventually, the node voltage 122 will increase sufficiently to equal the switching threshold value, Vsv, for the first inverter 130 at the end of the reset release interval 414. Vsv will be about ⅘ of the supply voltage at t4, e.g., Vdd-s (FIG. 5). Conducting channel widths and lengths Wp and Lp for transistor 112 are selected in combination with conducting channel widths and lengths Wn and Ln for transistor 114 to ensure that drain current 128 will charge the delay capacitor transistor 118 sufficiently slowly to create an additional time delay after Vdd>Vt1 such that the DFF 138 is guaranteed to be reset by time point t4.

The reset time interval, t-reset (220) for the DFF 138 is determined by the speed of the transistors in the flip-flop circuit 138, not shown. This is typically a matter of a few ns, which is short compared to the slowly varying recovery voltage of the power supply and the delay times generated by the power on reset circuit 100.

After the flip-flop circuit 138 has reset and initialized to its known state, (i.e., t reset+threshold time 209), the reset circuit output 136 remains active low for an additional time until power supply voltage has increased well beyond the value required for the flip-flop circuit to reset successfully. This is indicated by the positive going transition 402 in FIG. 4 which displays the output 136 of the power on reset circuit 100 during the voltage recovery of FIG. 1. The positive going transition 402 occurs at a delayed time 414, the reset release interval, indicated in FIG. 2, FIG. 4, and FIG. 6. This transition 402 is a reset completion signal that can be used by additional circuits on the same die, or by external circuits in related system functions to indicate the circuits have been reset.

The n-channel transistor 114 is selected to have a narrow and long channel, that is n-channel width, Wn, that is relatively narrow, and a channel length, L, that is relatively long. This is commonly referred to as a weak n-channel transistor. In FIG. 2, VDD recovers from essentially 0 volts at t0 to Vdd-max 206 at about 5.6 volts over a time interval 208 of about one millisecond. This represents behavior expected for a typical integrated circuit, e.g., a chip.

The charging current 128 supplied by a p-channel transistor 112 and the size of the charging capacitor Cn provided by n-channel transistor 118 is related to the switching threshold Vsv of the first inverter 130. In this circuit the switching threshold of 130 is set by the supply voltage at the positive rail 102, about 2 volts, and the relative strengths of the pull-up transistor 164 and pull down transistors 160, 162.

In order to provide sufficient time for the CMOS flip-flop 138 to reset after power supply voltage at node 102 reaches the sum of the p-channel and n-channel thresholds, the current capability of the transistor 112, the value of capacitance, Cn from transistor 118, and the inverter threshold, Vsv each are selected so that the reset release interval from the onset of the charging current 128 until voltage at node 122 reaches the switching threshold, Vsv, is long enough for the CMOS circuit 138 to reset before the inverter 130 switches, driving the output inverter node 136 from its active low reset level to a high level, releasing the R\ input of the flip-flop 138.

Protection Against Rapid Rampdown

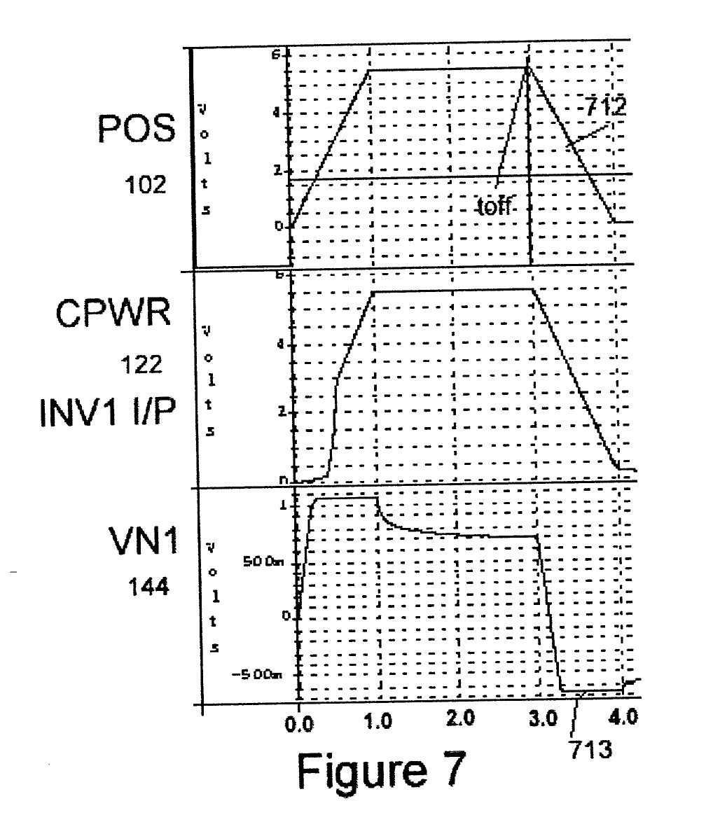

With regard to FIG. 7 and referring again to FIG. 1, another important element of the present power on reset invention shown by the circuit embodiment 100 is a voltage limiting clamp provided by a p-n junction clamp diode connected between the common gate-drain connection at node 111 and the node VSS, the negative supply. In this embodiment of the present invention PNP transistor 116 provides a p-n junction clamp diode by its base-emitter and base-collector junction with the p-type base connected to node 111 and the n-type emitter connected to node VSS. The function of the base-emitter and base-collector junction of 116 can be understood by considering another aspect of the power on reset circuit of the present invention. Suppose the power supply POS has been stable for some time indicated by arrow 710, and the circuit 100 is at equilibrium. There will be some voltage drop, e.g., approximately a NMOS threshold, Vtn, from the common gate-drain node 111 to the source of transistor 114 at node VSS. The voltage across C0 is thus approximately one threshold less than VDD because of the transistor 114. Therefore the base of PNP transistor Q one will be approximately one NMOS threshold above the negative supplies, VSS. Further, suppose the power supply Vdd is turned off abruptly as indicated by the negative-going ramp 712. As Vdd (and V(POS)) ramps down toward zero volts, the capacitor C0 will attempt to couple that ramp to the gate-drain of transistors 14, thereby taking charge out of the node 111 and driving node 111 negative with respect to node VSS.

With the 116 clamp diode connected, the most negative that node 111 can be with respect to node VSS is about one p-n junction diode drop 713, e.g., about 0.7 volts.

In the absence of the PNP transistor 116 (or its equivalent), the node 111, being the gate and drain of an NMOS transistor, could be driven considerably negative with respect to node VSS. The node 111 being reversed biased by the ramp 712, and any parasitic capacitance thereat, can store excess charge delivered by capacitor C0 for a substantial time, possibly causing circuit malfunction.

Understanding of this can be seen by further considering the consequence of the absence of PNP transistor 116 on the voltage at node 111. A sudden loss of power from Vdd will cause the ramp down 712 of POS to couple through C0, taking charge out of the node 111 possibly driving it below ground by as much as its full stored value of Vdd−Vtn. For typical values of C0 and the typically very small node capacitance values of CMOS circuits, 111 could be driven to a negative value 3 or 4 volts below the VSS supply. When the gate and drain voltage of transistor 114 is below the source voltage, the transistor 114 is shut off and there is nowhere for the charge stored at 111 to go, except for leakage current at node 111, which could be quite low. Then with the power supply Vdd at zero, stray node capacitance Cs (120), could retain a large stored voltage for a considerable time.

As a consequence, capacitor C0 would retain its stored voltage, VC0, approximately Vdd−Vtn. Stored voltage VC0 would appear directly across the gate-source terminals of p-channel 112, driving it heavily into conduction. As long as the stored voltage VC0 is retained on C0, the p-channel 112 acts as relatively low-value resistance connecting Vdd to the charging node 122.

At a later time, e.g., t0, when the Vdd power supply begins to recover, the POS voltage ramps up again. This would almost certainly be problematic, if the leakage current lcn of the n-channel transistor 114 at the node 111 were so low, that the power supply transition occurred before the stored voltage, VC0, at common node 111 had discharged sufficiently close to node VSS to reliably begin another time delay operation.

Node 111 could be as much as 3 or 4 volts negative with respect to ground after the power supply voltage dropped to 0, i.e., node VSS and capacitor C0 retains stored voltage,

At the very instant of POS ramp beginning to increase from zero toward Vdd, i.e., at time t0, the charging p-channel transistor 112 would already have the large negative voltage VC0 biasing its gate to source terminals. The p-channel 112 would be heavily biased into conduction, charging Vcn from the start.

The delay previously provided for node 111 to charge from zero to vtn, and to vtn+vtp, before the p-channel 112 became conducting would be irrelevant, because it would already be conducting, eliminating the delay factor from t3 to t4 as in FIG. 1. Additionally, since p-channel 112 would already be conducting heavily, the current Icp would increase substantially more quickly than the case of FIG. 1 and Vcn at node 122 would essentially track the Vdd. Thus there would be less delay between the time the DFF 138 supply voltage reached Vt1 and the time at which Vcn reaches the inverter threshold, Vsv. The inverters Inv1, Inv2 may then switch immediately therefore before the DFF 138 could perform its initialization reset function. This would be a false indication to the following circuits that the Vdd power supply had recovered, possibly causing a serious malfunction.

That would defeat the purpose of having C0 for initializing p-channel 112 with zero or low charging current at the beginning of a time delay generating event. An initial heavy charging current into the delay capacitor Cn would cause the time delay, t-del, to be much shorter than desired.

The base-emitter and base-collector junctions of the PNP transistor 116 provides a clamp that prevents the node 111 from being more than about 0.6 volts below the negative supply VSS, i.e., the diode voltage drop across the N-P base-emitter junction of 116. Thus 116 ensures that node 111 will be no more than about 0.6 volts below the VSS power supply and C0 will be charged to no more that one diode drop in the event there is another POS power supply transition from zero volts to Vdd.

This explains the function of the base-emitter junction of PNP transistor 116 in stabilizing the circuit so that it will generate the correct time delay, t-del, even if the power supply Vdd is toggled rapidly. The clamping function provided by the base-emitter junction of PNP transistor 116 could also be provided by a simple diode with its p-region connected to the VSS supply and its n-region connected to 111.

The PNP transistor 116 in this embodiment of the present invention is a parasitic device inherent in the CMOS process implementing the circuit of FIG. 1. Alternative embodiments of the present invention can take advantage of other processes that provide isolated p-n junctions to form the base-emitter diode clamping junction of 116.

Alternative embodiments of the present invention can be implemented using discrete components, e.g., separate packaged elements such as the n-channel transistor 114, p-channel 112, bipolar diode instead of transistor 116 and transistor 124 and fixed capacitors in place of C0 110 and Cn 118.

Referring again to FIG. 1, a resistor R1 (117) may be provided in the power on reset circuit for ESD protection as is known in the art. Resistor R1 117 is shown, but is not necessary for the functionality of the power on reset invention. R1 117 will generally be a parasitic or separate resistance whose value should be small enough so the time constant R1*C0 is small compared to the time interval between successive off-on power supply transitions, e.g., less than about ⅓ {toff to t0}. This assures that the circuit shown in FIG. 1 will be ready to accept a POS voltage recovery shortly following a POS voltage loss.

Note also that if the ESD protection resistor R1 is provided in the power-on reset circuit of the present invention, it does not appear directly across the power supply terminals (Vdd to Vss), but instead is coupled through the capacitor C0, and does not draw any DC current from the supplies.

Rapid Toggle Protection

PNP transistor 124 (Q2) provides another aspect of the present invention. After the circuit of FIG. 1 issues the positive going release reset edge at 414, and the power supply POS is stable, the capacitor C0 will be nearly fully charged to Vdd, minus only the Vtn of transistor 114. Thus the node 122 Vcn will tend to remain high, essentially at Vdd since it continues to be pulled up toward Vdd by the drain of p-channel 112 being driven by Vdd−Vtn across C0 110.

With regard to FIG. 7, after the power supply Vdd has been stable and the circuit 100 is in equilibrium, Vcn is most positive, essentially at Vdd when POS is fully recovered, e.g., at about 5 volts prior to the time toff shown FIG. 7, the emitter and base of Q2 then are both at the same potential and Q2 is off, drawing no current in normal operation. When node POS is brought low following a turn-off of the power supply Vdd, e.g., negative ramp 712, the base of 124 follows POS and forward biases the emitter-base junction of transistor 124 Q2. PNP 124 goes into its active region and starts to conduct, drawing base current Ib2 into the POS node. The current gain, beta-p, of Q2 cause emitter current le2=Ib2(beta-p+1) to flow, beginning to discharge the delay capacitor, Cn, and the causing voltage Vcn to discharge rapidly toward the substrate rail VSUB. As soon as node POS and the base of Q2 approach to within one diode drop of node VSS, the transistor Q2 turns off, leaving Vcn at no more than about 0.6 volts above the node VSS.

If there is residual voltage greater than Vtp remaining on capacitor C0 after node POS and the node VSS are at equal voltages, the p-channel 112 will continue to discharge the node Vcn toward equilibrium with node VSS. Otherwise, Vcn will remain at about 0.6 volts until leakage current (not shown) associated with the drain of p-channel 112 and the emitter of Q2 dissipates the remaining charge.

The transistor Q2 is provided by the grounded collector transistor structure inherently available in the P- substrate of an n-well CMOS technology. Alternative embodiments of the present invention may implement this aspect of the invention using transistor structures available in the implementing technology.

What is claimed is:

1. A power on reset signal generating circuit arrangement comprising:
delay means for generating a reset release signal delayed in time by a delay from a time at which a voltage between two voltage terminals has recovered to a first voltage level during a recovery of said voltage from essentially zero volts.

2. The circuit arrangement according to claim 1, wherein said delay means forms no DC current paths between said two voltage terminals.

3. The circuit arrangement according to claim 2, wherein said delayed reset release signal delay is derived from said recovery of said voltage.

4. The circuit arrangement according to claim 2, wherein said delay time is greater than a minimum reset release delay time.

5. The circuit arrangement according to claim 4, wherein said means comprises a capacitor wherein said minimum reset release delay time is responsive to said capacitor.

6. The circuit arrangement according to claim 4, further comprising a voltage-controlled device responsive to a voltage developed across said capacitor.

7. The circuit arrangement according to claim 4, further comprising a voltage clamping device coupled between one end of said fixed capacitor and one of said two terminals, said voltage clamping device configured to prevent a voltage difference greater than about 1 diode drop between said one end of said fixed capacitor and said one of said two terminals.

8. The circuit arrangement according to claim 1, wherein circuit elements are selected from the group consisting of 3-terminal transistors and capacitors.

9. The circuit arrangement according to claim 1, wherein resistor circuit elements are not connected between power supply terminals.

10. The circuit arrangement according to claim 8, wherein said voltage level is determined by values of electrical parameters characteristic of said elements.

11. The circuit arrangement according to claim 10, wherein said electrical parameters include MOS threshold voltage values.

12. The circuit arrangement according to claim 1, including a buffer isolating said delay means from circuits receiving said delayed signal.

13. The circuit arrangement according to claim 1, comprising a voltage controlled current source.

14. The circuit arrangement according to claim 1, comprising a voltage divider coupled between the two voltage terminals.

15. The circuit arrangement according to claim 14, wherein said voltage divider is a capacitor having one end connected to one of said voltage terminals and the other end connected to a first common connection with a control electrode and one of two controlled current conducting electrodes of a first 3-electrode current controlled device, in which the other current conducting electrode of said device is connected to said other of said voltage terminals.

16. The circuit arrangement according to claim 15, comprising a second 3-electrode current conducting device having a second control electrode and two second controlled current conducting electrodes wherein said second control electrode is connected to said first common connection, and one of said two second controlled current conducting electrodes is connected to said one end of said capacitor.

17. The circuit arrangement according to claim 16, comprising a second capacitor connected at one end to said other of said two second controlled current conducting electrodes and connected at its other end to said other of said voltage terminals.

18. The circuit arrangement according to claim 17, comprising a switching circuit having an input and an output responsive to said input in which said input is connected to said one end of said other of said two second controlled current conducing electrodes.

19. The circuit arrangement according to claim 18, in which said switching circuit defines a switching threshold value.

20. The circuit arrangement according to claim 19, in which said delay means comprises said switching threshold value, said capacitor, said first 3-electrode current controlled device, said second 3-electrode current controlled device, said first capacitor, and said second capacitor.

21. The circuit arrangement according to claim 17, comprising discharge means for discharging said first common connection to said other voltage terminal when said other voltage terminal is discharged from an initial voltage toward zero volts.

22. The circuit arrangement according to claim 17, comprising discharge means for discharging said one end of said other of said second capacitor to said other voltage terminal when said other voltage terminal is discharged from an initial voltage toward zero volts.
